(19) United States
(12) Patent Application Publication
(10) Pub. No.: US 2026/0068391 A1
(43) Pub. Date: Mar. 5, 2026

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Zhenhai YUE, Hefei (CN); Yuan YAO, Hefei (CN); Liusong NI, Hefei (CN); Manli CHEN, Hefei (CN); Xiujian ZHU, Kunshan (CN)

(73) Assignees: Hefei Visionox Technology Co., Ltd., Hefei (CN); Visionox Technology Inc., Kunshan (CN)

(21) Appl. No.: 19/309,496

(22) Filed: Aug. 25, 2025

(30) Foreign Application Priority Data
Sep. 2, 2024 (CN) 202411231554.2

(51) Int. Cl. H10H 29/49; H10H 29/37; H10H 29/39; H10H 29/80

(52) U.S. Cl. CPC H10H 29/49; H10H 29/37; H10H 29/39; H10H 29/8321

(57) ABSTRACT

The present disclosure provides a display panel and a method for manufacturing the same, and a display device. The display panel has an active area and a bezel area at least partially surrounding the active area. The display panel includes: a substrate; a first electrode layer, a light-emitting layer, and a second electrode layer that are sequentially stacked in a direction away from the substrate; a connection electrode layer located on one side of the substrate and provided with a connection electrode located in the bezel area, where the connection electrode transmits a signal to the second electrode layer; and a first wiring layer provided with a signal connection structure that transmits the signal to the connection electrode. The present disclosure enables signal transmission to a second electrode and improves flexibility in wiring of the display panel.

### CROSS-REFERENCE TO RELATED APPLICATION

The present application claims priority to Chinese Patent Application No. 202411231554.2, filed on Sep. 2, 2024, and entitled “DISPLAY PANEL AND DISPLAY DEVICE”, which is incorporated herein by reference in its entirety.

### FIELD

The present disclosure relates to the field of display technologies, and in particular to a display panel and a display device.

### BACKGROUND

With the continuous development of display technology, display panels have shown diversified development trends. Regardless of the type of display panel, there is a consistent pursuit of better wiring methods.

### SUMMARY

The present disclosure provides a display panel and a display device, to enable signal transmission to the display panel and improve flexibility in wiring.

A display panel is provided that has an active area and a bezel area at least partially surrounding the active area. The display panel includes:
a first electrode layer, a light-emitting layer, and a second electrode layer that are sequentially stacked in a direction away from the substrate;
a connection electrode layer located on one side of the substrate and provided with a connection electrode located in the bezel area, where the connection electrode transmits a signal to the second electrode layer; and
a first wiring layer provided with a signal connection structure that transmits the signal to the connection electrode.

In one embodiment, the display panel further includes:
an isolation structure disposed on one side of the substrate and provided with a first isolation opening.

In one embodiment, the connection electrode electrically connects the isolation structure and the signal connection structure, and the connection electrode and the isolation structure are disposed in a same layer and made of a same material.

In one embodiment, the connection electrode and the isolation structure are formed integrally.

In one embodiment, the display panel further includes a pixel define layer located on a side of the first electrode layer away from the substrate, where the pixel define layer includes a pixel opening exposing the first electrode, and the pixel opening is in communication with the isolation opening.

In one embodiment, the pixel define layer includes an inorganic insulating material.

In one embodiment, the isolation structure further includes a second isolation opening located in the bezel area, and the second isolation opening is a dummy isolation opening.

In one embodiment, a size, a shape, an arrangement manner, and a distribution density of the second isolation opening are the same as those of the first isolation opening.

In one embodiment, the display panel further includes a first planarization layer located on a side of the first electrode layer close to the substrate.

The first planarization layer is provided with a first via hole located in the bezel area, and the pixel define layer is provided with a second via hole located in the bezel area.

An orthographic projection of the first via hole on the substrate overlaps that of the second via hole on the substrate, and the connection electrode is connected to the signal connection structure through an overlapping area of the first via hole and the second via hole.

In one embodiment, a size of the first via hole is greater than that of the second via hole, and the orthographic projection of the second via hole on the substrate is within that of the first via hole on the substrate.

In one embodiment, the first wiring layer further includes a third via hole, and the third via hole is located in the bezel area.

In one embodiment, the third via hole includes a third via hole A and a third via hole B. An orthographic projection of the third via hole A on the substrate is within that of the connection electrode on the substrate, and an orthographic projection of the third via hole B on the substrate is outside that of the connection electrode on the substrate.

In one embodiment, the display panel further includes a dam structure located on a side of an area where the signal connection structure is located, the side being away from the active area. The first wiring layer extends from the area where the signal connection structure is located to an area where the dam structure is located. The orthographic projection of the third via hole B on the substrate overlaps that of the dam structure on the substrate.

In one embodiment, the isolation structure includes a first isolation portion and a second isolation portion that are sequentially stacked in the direction away from the substrate, and an orthographic projection of the first isolation portion on the substrate is within that of the second isolation portion on the substrate.

In one embodiment, the second electrode is electrically connected to the first isolation portion.

In one embodiment, the isolation structure further includes a third isolation portion located on a side of the first isolation portion away from the substrate. The orthographic projection of the first isolation portion on the substrate is within that of the third isolation portion on the substrate, and the second electrode is electrically connected to the third isolation portion.

In one embodiment, a material of the third isolation portion includes molybdenum metal; and/or a material of the first isolation portion includes aluminum metal; and/or a material of the second isolation portion includes titanium metal.

In one embodiment, the connection electrode includes a first connection electrode portion, a second connection electrode portion located on a side of the first connection electrode portion facing away from the substrate, and a third connection electrode portion located on a side of the first connection electrode portion facing the substrate. The second connection electrode portion protrudes from a side surface of the first connection electrode portion, and the third connection electrode portion protrudes from the side surface of the first connection electrode portion.

In one embodiment, an orthographic projection of the third connection electrode portion on the substrate is within that of the second connection electrode portion on the substrate.

In one embodiment, the first connection electrode portion and the first isolation portion are disposed in a same layer and made of a same material; the second connection electrode portion and the second isolation portion are disposed in a same layer and made of a same material; and the third connection electrode portion and the third isolation portion are disposed in a same layer and made of a same material.

In one embodiment, the connection electrode is of a block shape, and/or the signal connection structure is of a block shape.

In one embodiment, there is at least one connection electrode, and there is at least one signal connection structure. The signal connection structure and the connection electrode are in a one-to-one correspondence; and/or the signal connection structure and the connection electrode are in a many-to-one correspondence; and/or the signal connection structure and the connection electrode are in a one-to-many correspondence.

In one embodiment, electrical signals transmitted on respective connection electrodes are the same; or electrical signals transmitted on respective connection electrodes are different.

In one embodiment, the display panel further includes at least two second wiring layers located between the substrate and the first wiring layer.

In one embodiment, the at least two second wiring layers include a first metal layer, a second metal layer, a third metal layer, and a fourth metal layer that are sequentially stacked in the direction away from the substrate; and the first wiring layer is a fifth metal layer.

In one embodiment, at least in the active area, the first metal layer is provided with a gate of a transistor, the second metal layer is provided with capacitor plates, the third metal layer is provided with a source and a drain of the transistor, and the fourth metal layer is provided with a first intermediate trace connected to the first electrode.

In one embodiment, the at least two second wiring layers include a first metal layer, a second metal layer, and a third metal layer; and the first wiring layer is a fourth metal layer.

In one embodiment, at least in the active area, the first metal layer is provided with a gate of a transistor, the second metal layer is provided with capacitor plates, and the third metal layer is provided with a source and a drain of the transistor.

In one embodiment, the first electrode layer includes a first electrode, the light-emitting layer includes a light-emitting portion, and the second electrode layer includes a second electrode. The first electrode, the light-emitting portion, and the second electrode form a light-emitting device.

The light-emitting device includes a first light-emitting device and a second light-emitting device that emit light of different colors, and the signal connection structure includes a first signal connection structure and a second signal connection structure. The first signal connection structure is electrically connected to the first light-emitting device, and the second signal connection structure is electrically connected to the second light-emitting device.

In one embodiment, the first electrode layer includes a first electrode, the light-emitting layer includes a light-emitting portion, and the second electrode layer includes a second electrode. The first electrode, the light-emitting portion, and the second electrode form a light-emitting device.

The light-emitting device includes a first light-emitting device and a second light-emitting device that emit light of different colors, and the signal connection structure transmits a same signal to the first light-emitting device and the second light-emitting device.

Correspondingly, the present disclosure further provides a display device. The display device includes: a display panel according to any embodiment of the present disclosure.

The present disclosure further provides a display panel having an active area and a bezel area at least partially surrounding the active area. The display panel includes:
a substrate;
a first electrode layer, a light-emitting layer, and a second electrode layer that are sequentially stacked in a direction away from the substrate;
at least two insulating layers that are located in the bezel area and sequentially stacked in a direction away from the substrate, where the at least two insulating layers have nested through holes; and
a connection electrode layer provided with a connection electrode located in the bezel area and a first wiring layer provided with a signal connection structure, where the signal connection structure transmits a signal to the connection electrode through the nested holes, and the connection electrode transmits a signal to the second electrode layer.

In one embodiment, the at least two insulating layers include:
a first planarization layer located on a side of the first electrode layer close to the substrate and provided with a first via hole located in the bezel area; and
a pixel define layer located on a side of the first electrode layer away from the substrate and provided with a second via hole located in the bezel area, where the first via hole and the second via hole form the nested holes.

In one embodiment, an orthographic projection of the first via hole on the substrate overlaps that of the second via hole on the substrate, and the connection electrode is connected to the signal connection structure through an overlapping area of the first via hole and the second via hole.

In one embodiment, a size of the first via hole is greater than that of the second via hole, and the orthographic projection of the first via hole on the substrate covers that of the second via hole on the substrate.

In the embodiments of the present disclosure, the second electrode is configured to be connected to the first wiring layer through the connection electrode in the bezel area, and signal transmission to the second electrode is enabled and flexibility in wiring of the display panel is improved.

The content described in this section is not intended to identify features of embodiments of the present disclosure, and not intended to limit the present disclosure. Other features of the present disclosure will be understood through the following description.

### BRIEF DESCRIPTION OF THE DRAWINGS

In order to more describe the embodiments of the present disclosure, the drawings used for describing the embodiments will be briefly described below. The drawings in the following description are only some embodiments of the present disclosure, and other drawings can be obtained from the drawings.

FIG. 1 is a schematic sectional view of a display panel according to an embodiment of the present disclosure;

FIG. 2 is a schematic sectional view of another display panel according to an embodiment of the present disclosure;

FIG. 3 is a schematic sectional view of yet another display panel according to an embodiment of the present disclosure;

FIG. 4 is a schematic sectional view of yet another display panel according to an embodiment of the present disclosure;

FIG. 5 is a schematic top view of a display panel according to an embodiment of the present disclosure;

FIG. 6 is a schematic view of a section along A-A in FIG. 5;

FIG. 7 is a schematic top view of another display panel according to an embodiment of the present disclosure;

FIG. 8 is a schematic view of a section along E-E in FIG. 7;

FIG. 9 is a schematic top view of yet another display panel according to an embodiment of the present disclosure;

FIG. 10 is a schematic view of a section along B-B in FIG. 9;

FIG. 11 is a schematic top view of yet another display panel according to an embodiment of the present disclosure;

FIG. 12 is a schematic view of a section along C-C in FIG. 11;

FIG. 13 is a schematic top view of yet another display panel according to an embodiment of the present disclosure;

FIG. 14 is a schematic top view of another display panel according to an embodiment of the present disclosure;

FIG. 15 is a schematic top view of yet another display panel according to an embodiment of the present disclosure;

FIG. 16 is a schematic sectional view of yet another display panel according to an embodiment of the present disclosure;

FIG. 17 is a schematic top view of yet another display panel according to an embodiment of the present disclosure;

FIG. 18 is a schematic view of a section along D-D in FIG. 17;

FIG. 19 is a schematic sectional view of yet another display panel according to an embodiment of the present disclosure;

FIG. 20 is a schematic sectional view of yet another display panel according to an embodiment of the present disclosure;

FIG. 21 is a schematic structural diagram depicting steps of a method for manufacturing a display panel according to an embodiment of the present disclosure; and

FIG. 22 is a schematic structural diagram depicting steps of another method for manufacturing a display panel according to an embodiment of the present disclosure.

### DETAILED DESCRIPTION OF THE EMBODIMENTS

For a better understanding of the embodiments of the present disclosure, the embodiments in the embodiments of the present disclosure will be completely described below with reference to the accompanying drawings for the embodiments of the present disclosure. The described embodiments are merely some of, rather than all of, the embodiments of the present disclosure. All other embodiments obtained based on the embodiments of the present disclosure shall fall within the protection of the present disclosure.

It is noted that, in the description, claims, and accompanying drawings of the present disclosure, the terms such as “first” and “second” are used for distinguishing similar objects, but are not necessarily used for describing a specific sequence or order. The data termed in such a way is interchangeable in proper circumstances and the embodiments of the present disclosure described herein can be implemented in an order other than the order illustrated or described herein. In addition, the terms “including” and “having”, and any variations thereof, are intended to cover a non-exclusive inclusion, In one embodiment, a process, method, system, product, or device including a series of steps or units is not necessarily limited to those steps or units explicitly listed, and may include other steps or units not explicitly listed or inherent to the process, method, product, or device.

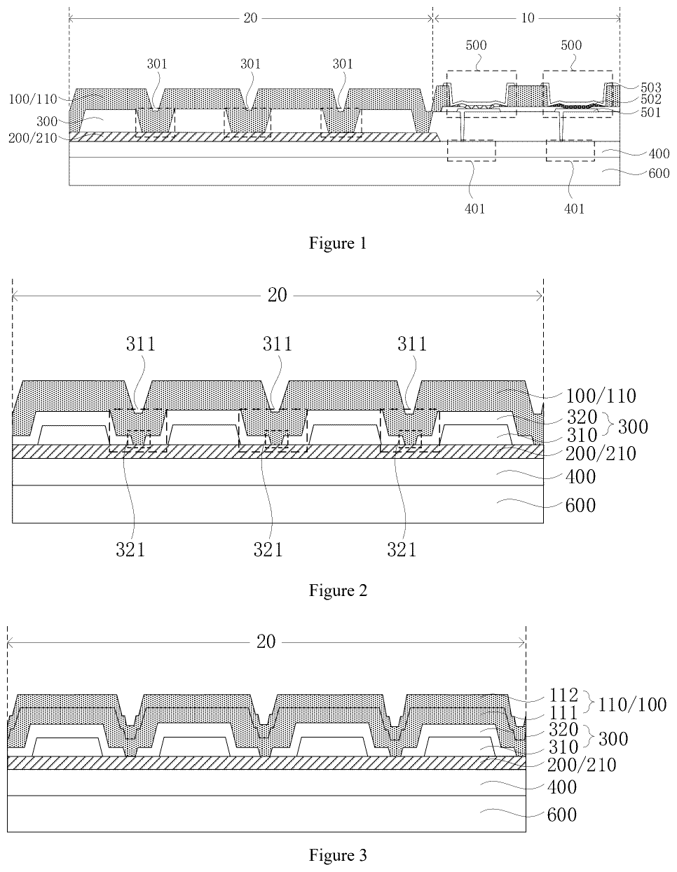

An embodiment of the present disclosure provide a display panel. FIG. 1 is a schematic sectional view of a display panel according to an embodiment of the present disclosure. Referring to FIG. 1, the display panel includes an active area 10 and a bezel area 20 at least partially surrounding the active area 10. The display panel further includes:
a substrate 600;
a first electrode layer 501, a light-emitting layer 502, and a second electrode layer 503 that are sequentially stacked in a direction away from the substrate 600;
a connection electrode layer 100 located on one side of the substrate 600 and provided with a connection electrode 110 located in the bezel area 20, where the connection electrode 110 transmits a signal to the second electrode layer 503; and
a first wiring layer 200 provided with a signal connection structure 210 that transmits the signal to the connection electrode 110.

The first electrode layer 501 includes a first electrode, the light-emitting layer 502 includes a light-emitting portion, the second electrode layer 503 includes a second electrode, and the first electrode, the light-emitting portion, and the second electrode form a light-emitting device 500. In one embodiment, the first electrode is an anode, and the second electrode is a cathode. An anode of each light-emitting device 500 is powered separately through a pixel circuit 401; that is, the anode of each light-emitting device 500 is discretely disposed. A cathode of each light-emitting device 500 is connected to the same potential (that is, a common potential). The connection electrode 100 is configured to supply a common potential to the cathode. The connection electrode 110 may be provided as a whole block to reduce loss of the common potential during transmission.

Further, the first wiring layer 200 is a conductive film layer in an array layer. An additional film layer 400 of the array layer is disposed between the substrate 600 and the first wiring layer 200. The array layer may be, in one embodiment, a film layer provided with a device such as a transistor or a capacitor. The transistor and the capacitor form the pixel circuit 401. The first wiring layer 200 may be disposed in the same layer and made of the same material as the film layer where the device such as the transistor or capacitor is located, or may be a separate film layer. The first electrode (e.g., the anode) connected to the pixel circuit 401 is closer to the array layer, and the second electrode (e.g., the cathode) connected to the common potential is farther away from the array layer.

In this embodiment of the present disclosure, the second electrode is configured to be connected to the first wiring layer 200 through the connection electrode 110, and the first wiring layer 200 is connected to a desired signal, enabling signal transmission on the connection electrode 110. This embodiment of the present disclosure provides a wiring method for transmitting a signal to the second electrode, which is completely different from the related art, and the flexibility in wiring of the display panel is improved.

Further, in some related technologies, the second electrode layer directly extends from the active area 10 to the bezel area 20 and is connected to a signal transmission line. The second electrode layer is a film layer close to a top layer of the display panel. The second electrode layer in the active area 10 has a complete encapsulation layer for moisture isolation, while the second electrode layer in the bezel area 20 usually has a weak encapsulation (in one embodiment, there is a reduced number of encapsulation layers or no encapsulation layer). Therefore, a wiring structure in the related art is susceptible to moisture ingress, resulting in corrosion. Compared with the second electrode layer, the connection electrode layer 100 is resistant to moisture ingress and is less prone to corrosion.

Still referring to FIG. 1, in one embodiment, the display panel further includes an insulating layer 300. The insulating layer 300 is located between the connection electrode layer 100 and the first wiring layer 200. The insulating layer 300 is provided with a via hole 301, and the connection electrode 110 is connected to the signal connection structure 210 through the via hole 301. The insulating layer 300 being disposed between the connection electrode layer 100 and the first wiring layer 200 indicates that the connection electrode layer 100 and the first wiring layer 200 are located in different film layers.

In the embodiments described above, a manner in which the insulating layer 300 between the connection electrode layer 100 and the first wiring layer 200 is disposed varies according to different types of the display panel and different positions of the first wiring layer 200.

Still referring to FIG. 1, in an embodiment, the insulating layer 300 is a first planarization layer. That is, the connection electrode layer 100 is disposed above the first planarization layer, and the first wiring layer 200 is disposed below the first planarization layer. The first planarization layer is a film layer with a planarization function. Disposing the first planarization layer on the array layer facilitates planarization of an uneven surface of the array layer that is caused due to arrangement of transistors and other wirings. In one embodiment, a material of the first planarization layer is an insulating material such as an organic material and/or an inorganic material. In practical applications, the first planarization layer may be set to be thicker or thinner as needed. The first planarization layer may be a single-layer film layer, a dual-layer film layer, or a multi-layer film layer. In this embodiment of the present disclosure, the insulating layer 300 is configured to be the first planarization layer. In other words, the connection electrode layer 100, the first planarization layer, and the first wiring layer 200 are sequentially stacked. Providing the via hole on the first planarization layer facilitates connection between the connection electrode layer 100 and the first wiring layer 200.

Still referring to FIG. 1, in another embodiment, the insulating layer 300 is a pixel define layer. That is, the connection electrode layer 100 is disposed above the pixel define layer, and the first wiring layer 200 is disposed below the pixel define layer. The pixel define layer is a film layer with a pixel defining function. By providing a pixel opening (not shown in FIG. 1) different from the via hole 301 on the pixel define layer, and disposing in the pixel opening a film layer forming the light-emitting device 500, the light-emitting device 500 of which a shape is determined by a shape of the pixel opening may be formed. In one embodiment, a material of the pixel define layer is an organic insulating material, an inorganic insulating material, and/or the like. In practical applications, the pixel define layer may be set to be thicker or thinner as needed. The pixel define layer may be a single-layer film layer, a dual-layer film layer, or a multi-layer film layer. In this embodiment of the present disclosure, the insulating layer 300 is configured to be the pixel define layer. In other words, the connection electrode layer 100, the pixel define layer, and the first wiring layer 200 are sequentially stacked. Providing the via hole on the pixel define layer facilitates connection between the connection electrode layer 100 and the first wiring layer 200.

FIG. 2 is a schematic sectional view of another display panel according to an embodiment of the present disclosure. Referring to FIG. 2, in yet another embodiment, the insulating layer 300 includes a first planarization layer 310 and a pixel define layer 320. The first wiring layer 200, the first planarization layer 310, the pixel define layer 320, and the connection electrode layer 100 are sequentially stacked. The first planarization layer 310 is provided with a first via hole 311 located in the bezel area 20, and the pixel define layer 320 is provided with a second via hole 321 located in the bezel area. An orthographic projection of the first via hole 311 on the substrate 600 overlaps that of the second via hole 321 on the substrate 600. The first via hole 311 and the second via hole 321 form nested holes. The connection electrode 110 is connected to the signal connection structure 210 through an overlapping area of the first via hole 311 and the second via hole 321.

In one embodiment, a size of the first via hole 311 is greater than that of the second via hole 321, and the orthographic projection of the second via hole 321 on the substrate 600 is within that of the first via hole 311 on the substrate 600. After the first planarization layer 310 is formed, an entire pixel define material layer is formed thereon, including a film layer within the first via hole 311 and a film layer outside the first via hole 311, and then etching is performed to form the second via hole 321 within the first via hole 311. This preparation process is simple, and no etching residue is likely to form in the nested holes formed by the first via hole 311 and the second via hole 321, to facilitate reliable connection between the connection electrode 110 and the signal connection structure 210.

In some embodiments, the insulating layer 300 includes the first planarization layer 310 and the pixel define layer 320, where the first planarization layer 310 and the pixel define layer 320 are the insulating layer above the array layer, which indicates that the first wiring layer 200 is a wiring layer on the top layer of the array layer. In this embodiment of the present disclosure, the insulating layer 300 located between the connection electrode layer 100 and the first wiring layer 200 is configured to include only the first planarization layer 310 and the pixel define layer 320, and there is a relatively small number of layers in the insulating layer 300 between the connection electrode layer 100 and the first wiring layer 200, to reduce difficulty in signal transmission from the connection electrode layer 100 through the first wiring layer 200, and simplifying the preparation process.

In some other embodiments, in one embodiment, the insulating layer 300 further includes an additional film layer, which is not limited in the present disclosure.

Still referring to FIG. 2, in one embodiment, the size of the first via hole 311 is greater than that of the second via hole 321, and the orthographic projection of the first via hole 311 on the substrate 600 covers that of the second via hole 321 on the substrate 600. Such a configuration is reduces difficulty in preparation of the display panel and is easy to implement.

FIG. 3 is a schematic sectional view of yet another display panel according to an embodiment of the present disclosure. Referring to FIG. 3, in one embodiment, the connection electrode layer 100 includes at least two conductive layers. In one embodiment, the connection electrode layer 100 includes a first conductive layer 111 and a second conductive layer 112 that are stacked. In this embodiment of the present disclosure, such a configuration reduces resistance of the connection electrode layer 100, to improve display uniformity.

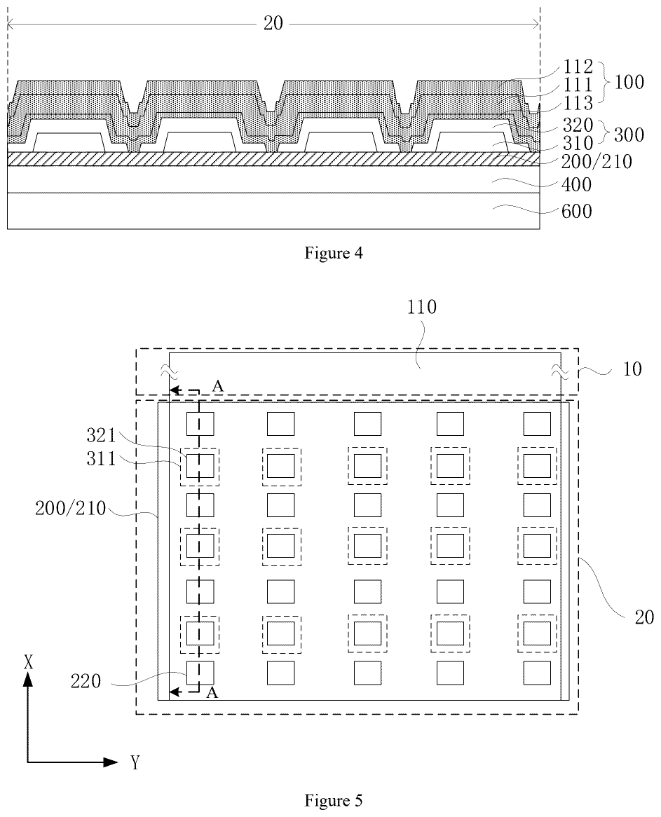

FIG. 4 is a schematic sectional view of yet another display panel according to an embodiment of the present disclosure. Referring to FIG. 4, in one embodiment, the connection electrode layer 100 includes a third conductive layer 113, the first conductive layer 111, and the second conductive layer 112 that are stacked. In one embodiment, a material of the third conductive layer 113 includes molybdenum metal, a material of the first conductive layer 111 includes aluminum metal, and a material of the second conductive layer 112 includes titanium metal. In this embodiment of the present disclosure, such a configuration reduces resistance of the connection electrode layer 100, to improve display uniformity.

FIG. 5 is a schematic top view of a display panel according to an embodiment of the present disclosure. Referring to FIG. 5, in one embodiment, the display panel includes the active area 10 and the bezel area 20, and the signal connection structure 210 is located in the bezel area 20. The signal connection structure 210 is disposed in the bezel area 20 for transmitting a signal from the connection electrode layer 100 in the active area 10 to the bezel area 20.

Still referring to FIG. 5, in one embodiment, the connection electrode 110 is of a block shape, and the signal connection structure 210 is of a block shape. This configuration allows the connection electrode 110 and the signal connection structure 210 each to have a large cross-sectional area, to reduce a voltage drop during transmission of a signal of the second electrode layer, to improve uniformity of signal transmission, and to improve display uniformity.

Still referring to FIG. 5, in one embodiment, there is one connection electrode 110, and there is one signal connection structure 210. The signal connection structure 210 and the connection electrode 110 are in a one-to-one correspondence. With reference to FIG. 1 to FIG. 5, the connection electrode 110 and the signal connection structure 210 overlap in the bezel area 20, and are thus connected through the via hole 301 on the insulating layer 300.

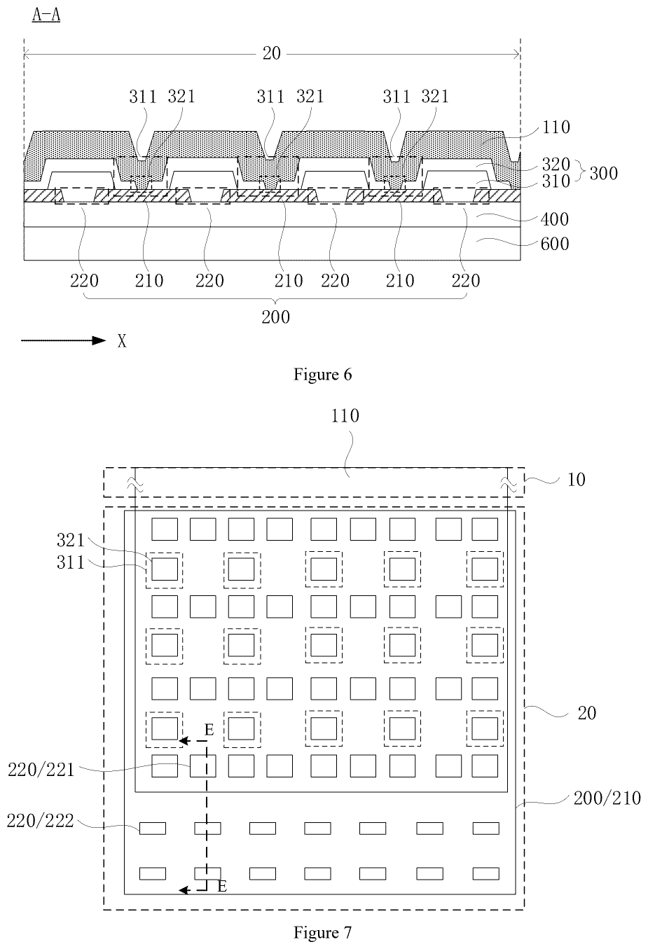

FIG. 6 is a schematic view of a section along A-A in FIG. 5. With reference to FIG. 5 and FIG. 6, in one embodiment, the first wiring layer 200 further includes a third via hole 220, and the third via hole 220 is located in the bezel area 20. Since the signal connection structure 210 is of a block structure in the bezel area 20 and has a relatively large area, providing the third via hole 220 in the signal connection structure 210 facilitates discharge of moisture generated from a lower film layer in the preparation process, to avoid the problem of film layer separation and peeling off caused by the inability to discharge the moisture.

Still referring to FIG. 5 and FIG. 6, the insulating layer 300 is filled in the third via hole 220. In one embodiment, when a film layer in the insulating layer 300 that is in direct contact with the signal connection structure 210 is the first planarization layer 310, the first planarization layer 310 is filled in the third via hole 220. Such a configuration is conducive to process simplification and enhancement of the structural stability of the display panel.

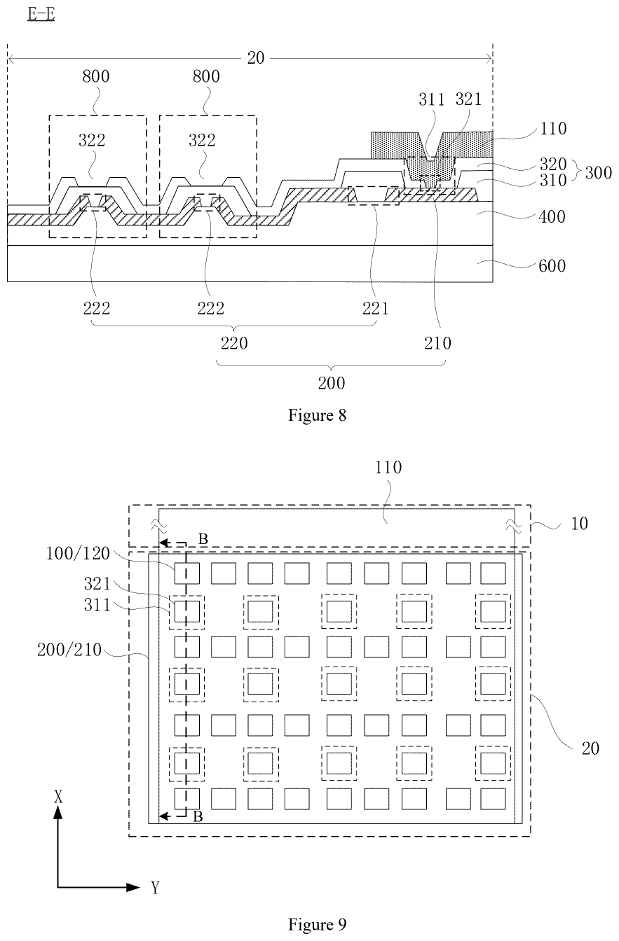

FIG. 7 is a schematic top view of another display panel according to an embodiment of the present disclosure, and FIG. 8 is a schematic view of a section along E-E in FIG. 7. Referring to FIG. 7 and FIG. 8, in one embodiment, the third via hole 220 includes a third via hole A 221 and a third via hole B 222. An orthographic projection of the third via hole A 221 on the substrate 600 is within that of the connection electrode 110 on the substrate 600, and an orthographic projection of the third via hole B 222 on the substrate 600 is outside that of the connection electrode 110 on the substrate 600. The third via hole A 221 and the third via hole B 222 are distributed at different positions of the first wiring layer 200. This further facilitates discharge of the moisture generated from the lower film layer in the preparation process, to avoid the problem of film layer separation and peeling off caused by the inability to discharge the moisture.

A difference between the third via hole B 222 and the third via hole A 221 is that the third via hole B 222 is not covered by the connection electrode 110. The shape and size of the third via hole B 222 may be the same as or different from those of the third via hole A 221, which may be set as needed in practical applications.

Still referring to FIG. 7 and FIG. 8, in an embodiment, the display panel further includes a dam structure 800, and the dam structure 800 is located on a side of an area where the signal connection structure 210 is located, the side being away from the active area 10. The first wiring layer 200 extends from the area where the signal connection structure 210 is located to an area where the dam structure 800 is located. The orthographic projection of the third via hole B 222 on the substrate 600 overlaps that of the dam structure 800 on the substrate 600. In one embodiment, to adapt to the size of the dam structure 800, the size of the third via hole B 222 is less than that of the third via hole A 221. Such a configuration facilitates discharge of moisture generated from a film layer of the dam structure 800, to improve air permeability of the signal dam structure 800 and prevent the problem of film layer separation and peeling off, to enhance stability of the dam structure 800.

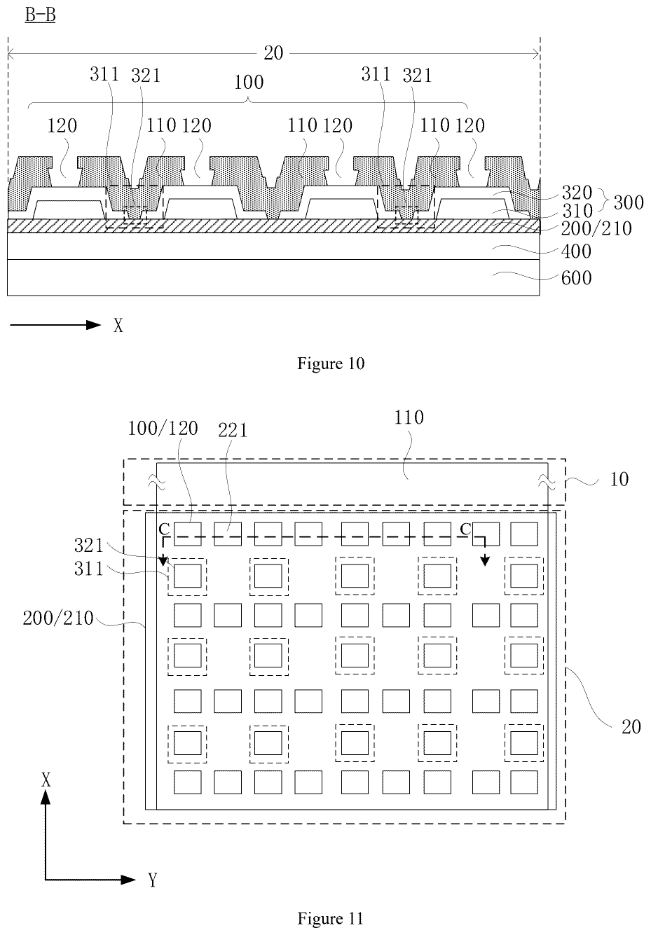

FIG. 9 is a schematic top view of yet another display panel according to an embodiment of the present disclosure, and FIG. 10 is a schematic view of a section along B-B in FIG. 9. Referring to FIG. 9 and FIG. 10, in one embodiment, the connection electrode layer 100 further includes a fourth via hole 120, and the fourth via hole 120 is located in the bezel area 20 and runs through the connection electrode layer 100. A material of the insulating layer 300 below the connection electrode layer 100 may be, in one embodiment, an organic material, and a material of the connection electrode layer 100 may be, in one embodiment, a metal material. A physical vapor deposition (PVD) process is used during the process of preparing the connection electrode layer 100. This process involves heating the display panel. During heating, moisture is generated from the insulating layer 300. The moisture can evaporate through the fourth via hole 120, which allows the moisture to be discharged. In this way, the problem of film layer separation and peeling off caused by the inability to discharge the moisture is avoided.

Still referring to FIG. 9 and FIG. 10, in one embodiment, in a first direction X, an orthographic projection of the fourth via hole 120 on the substrate 600 and that of the via hole of the insulating layer 300 (e.g., the first via hole 311 and the second via hole 321) on the substrate 600 are arranged in a staggered manner. In one embodiment, the first direction X is an arrangement direction of the active area 10 and the bezel area 20. In one embodiment, the first direction X is a long side direction of the display panel. The bezel area 20 shown in FIG. 9 and FIG. 10 is an upper bezel or a lower bezel. Such a configuration ensures reliable contact between the connection electrode 110 and the signal connection structure 210. That is, the provision of the fourth via hole 120 does not affect continuity of the signal of the connection electrode 110.

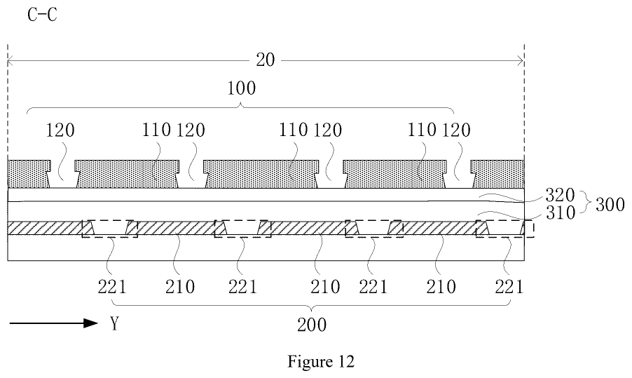

FIG. 11 is a schematic top view of yet another display panel according to an embodiment of the present disclosure, and FIG. 12 is a schematic view of a section along C-C in FIG. 11. Referring to FIG. 11 and FIG. 12, in an embodiment, in a second direction Y, the orthographic projection of the fourth via hole 120 on the substrate 600 and that of the third via hole A 221 on the substrate 600 are arranged in a staggered manner. In one embodiment, the second direction Y intersects with the first direction X. In one embodiment, the second direction Y perpendicularly intersects with the first direction X.

It should be noted that there may be a number of variations of the arrangement manner of the via hole (in one embodiment, the first via hole 311 and the second via hole 321) of the insulating layer 300, the third via hole 220, and the fourth via hole 120. In one embodiment, in the embodiment shown in FIG. 5, in the first direction X, the orthographic projection of the via hole (in one embodiment, the first via hole 311 and the second via hole 321) of the insulating layer 300 on the substrate 600 and that of the third via hole 220 on the substrate 600 are arranged in a staggered manner.

It should also be noted that in the embodiments described above, by way of example, the signal connection structure 210 is shown to be located in the bezel area 20, which is not intended to limit the present disclosure. In other embodiments, the signal connection structure 210 may be configured to be partially located in the active area 10, or the like.

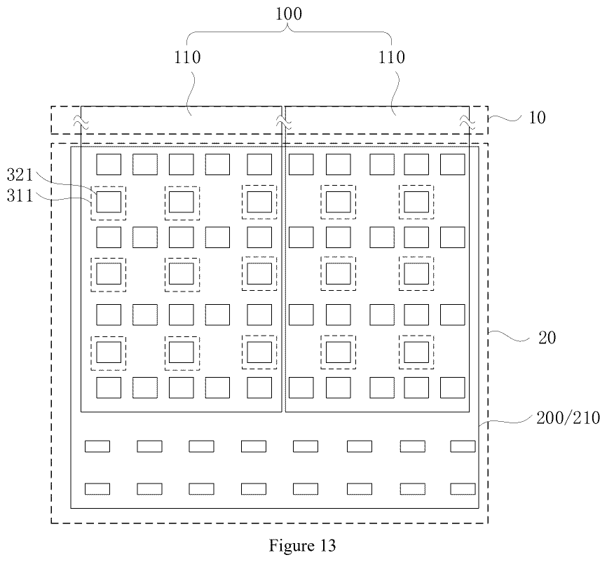

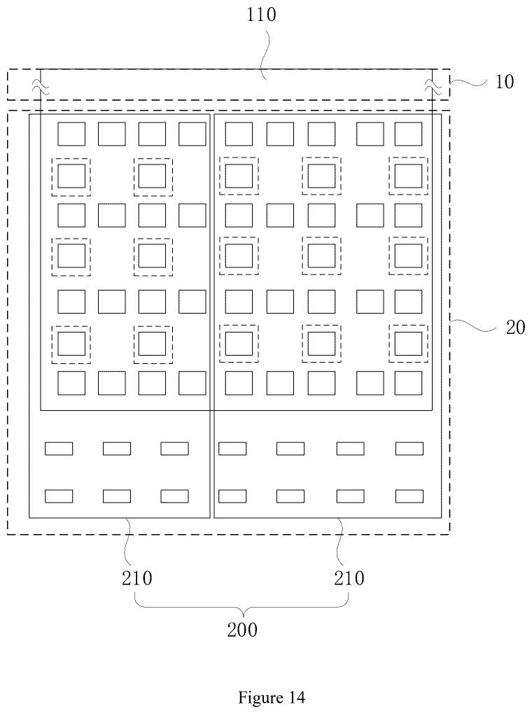

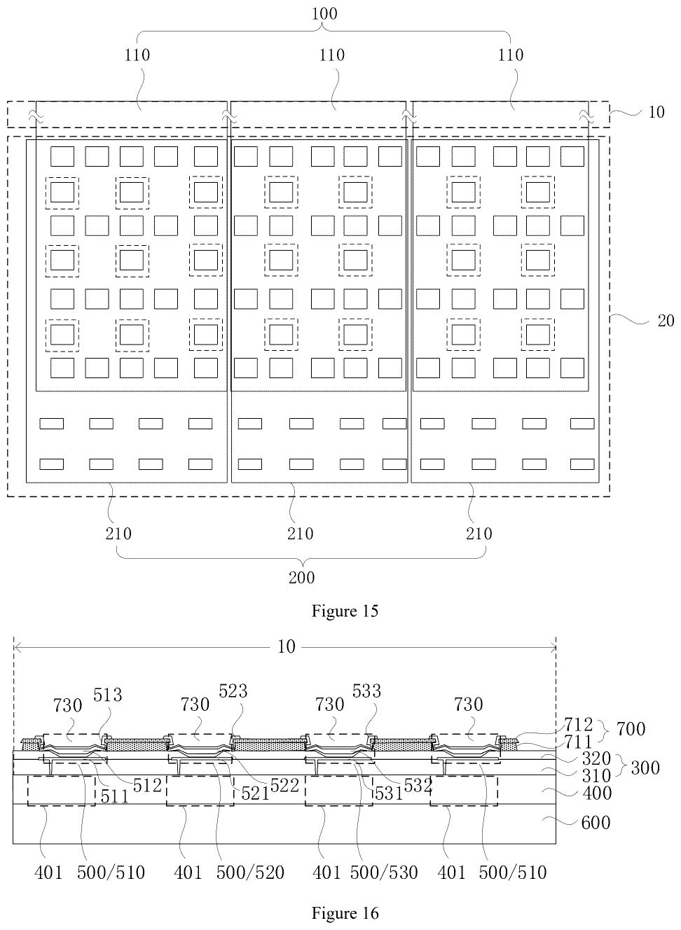

It should also be noted that in the embodiments described above, by way of example, there are one connection electrode 110 and one signal connection structure 210 shown, which is not intended to limit the present disclosure. In other embodiments, at least two connection electrodes 110 may be provided, and at least two signal connection structures 210 may be provided. As shown in FIG. 13, there is one signal connection structure 210 and two connection electrodes 110, and the signal connection structure 210 and the connection electrodes 110 are in a one-to-many correspondence. As shown in FIG. 14, there are two signal connection structures 210 and one connection electrode 110, and the signal connection structures 210 and the connection electrode 110 are in a many-to-one correspondence. As shown in FIG. 15, there are three signal connection structures 210 and three connection electrodes 110, and the signal connection structures 210 and the connection electrodes 110 are in a one-to-one correspondence.

Still referring to FIG. 15, in an embodiment, signals applied to the connection electrodes 110 are the same.

Still referring to FIG. 15, in another embodiment, electrical signals transmitted on the connection electrodes 110 are different. In one embodiment, different connection electrodes 100 transmit electrical signals of different common potentials to light-emitting devices 500 of different colors, respectively, to implement separate control of the connection electrodes 110 for the light-emitting devices 500 of various colors.

FIG. 16 is a schematic sectional view of yet another display panel according to an embodiment of the present disclosure. Referring to FIG. 16, in one embodiment, the display panel further includes an isolation structure 700. The isolation structure 700 is disposed on one side of the substrate 600, and the isolation structure 700 is provided with a first isolation opening 730. At least part of the light-emitting device 500 is disposed in the first isolation opening 730, and adjacent light-emitting devices 500 are separated at the isolation structure 700 to avoid crosstalk between the adjacent light-emitting devices 500 (e.g., a first light-emitting device 510 and a second light-emitting device 520).

It should be noted that for solutions related to the isolation structure, refer to patents (applications) No. PCT/CN2023/134518, CN202310619767.1, CN202310492119.4, CN202311346196.5. CN202310775778.9, etc., in which a structure, a material, and a preparation method of the isolation structure is described, the contents of which are incorporated herein by reference in their entireties.

Still referring to FIG. 16, in one embodiment, the first electrode layer includes a first electrode (in one embodiment, first electrodes 511, 521, and 531), the second electrode layer includes a second electrode (in one embodiment, second electrodes 513, 523, and 533), and the second electrode is located in the first isolation opening 730 and is electrically connected to the isolation structure 700. In one embodiment, in the active area 10, an orthographic projection of the isolation structure 700 on the substrate 600 has a mesh structure. The first isolation opening 730 has a mesh structure. The light-emitting layer includes a light-emitting portion (e.g., light-emitting portions 512, 522, and 532), and the light-emitting portion is located in the first isolation opening 730.

The isolation structure 700 has a specific thickness. In one embodiment, the thickness of the isolation structure 700 is greater than that of the second electrode (e.g., the cathode). In one embodiment, during the preparation of the display panel, after the isolation structure 700 is prepared, the light-emitting layer may be deposited using the isolation structure 700 as a mask, and the isolation structure 700 is used to separate light-emitting portions (including the light-emitting portions 512, 522, and 532) of the adjacent light-emitting devices 500 at the isolation structure 700. The light-emitting portions may not be in contact with the isolation structure 700, to avoid color crosstalk that occurs when the adjacent light-emitting devices 700 emit light of different colors. In one embodiment, the use of a fine metal mask for depositing a light-emitting portion in the related art can be saved. During the preparation of the second electrode on the light-emitting portion, in one embodiment, when the second electrode layer is deposited using a common metal mask, the presence of the isolation structure 700 separates the second electrode layer into a number of independent second electrodes one-to-one corresponding to the light-emitting devices 500. The preparation process of the second electrode layer is not limited to the evaporation process as described above, and a sputtering process or other processes may also be used, which is not specifically limited in this embodiment. It should be noted that when both the light-emitting layer and the second electrode layer are prepared using the evaporation process, an evaporation angle may be adjusted to make at least part of the light-emitting portion not in contact with the isolation structure 700, and the second electrode in contact with the isolation structure 700 to achieve a lap between the two.

The isolation structure 700 serves to isolate light-emitting layers of different light-emitting devices 500, and thus the isolation structure 700 has a specific thickness. In one embodiment, the thickness of the isolation structure 700 is greater than that of the second electrode. Therefore, a sheet resistance of the isolation structure 700 is small (in one embodiment, the sheet resistance of the isolation structure 700 is less than or equal to 0.005 ohms), which reduces a lap resistance of the second electrode through the isolation structure 700. This reduces heat generated at a lap point, a rate of temperature rise of a screen and power consumption of the screen, and accelerated aging of the light-emitting device 500 near a lap area, to improve display quality.

Still referring to FIG. 16, in one embodiment, the pixel define layer 320 is located on a side of the first electrode layer away from the substrate 600, and the first planarization layer 310 is located on a side of the first electrode layer close to the substrate 600. That is, the first electrode layer is located between the first planarization layer 310 and the pixel define layer 320. The pixel define layer 320 includes a pixel opening exposing the first electrode (e.g., the first electrode 513 and the first electrode 523), and the pixel opening is in communication with the first isolation opening 730.

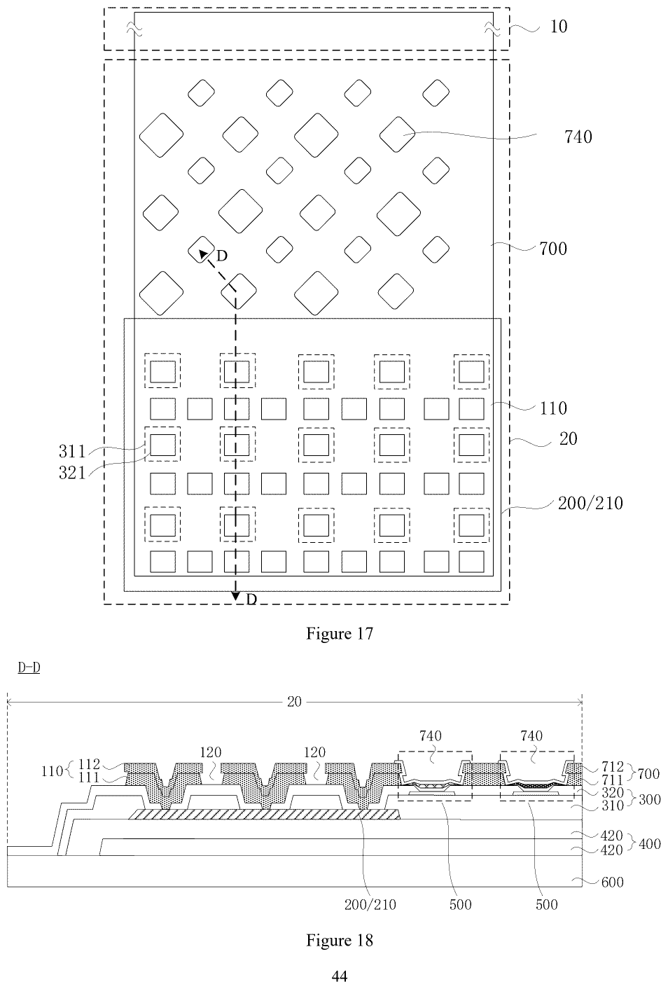

FIG. 17 is a schematic top view of yet another display panel according to an embodiment of the present disclosure, and FIG. 18 is a schematic view of a section along D-D in FIG. 17. Referring to FIG. 17 and FIG. 18, in one embodiment, the isolation structure 700 further includes a second isolation opening 740 located in the bezel area 20, and the second isolation opening 740 is a dummy isolation opening. The second isolation opening 740 is similar to the first isolation opening, and the second isolation opening 740 also has film layers of the light-emitting device 500 provided therein. Different from the first isolation opening, the light-emitting device 500 in the second isolation opening 740 does not emit light, and thus the light-emitting device 500 in the second isolation opening 740 does not need to be provided with a corresponding pixel circuit. Such a configuration improves uniformity of the display panel.

In one embodiment, a size, a shape, an arrangement manner, and a distribution density of the second isolation opening 740 are the same as those of the first isolation opening, to further improve uniformity of the display panel.

It should be noted that, due to the provision of the second isolation opening 740, an outer side of the second isolation opening 740 farthest away from the active area 10 is used as a boundary line between the connection electrode 110 and the isolation structure 700.

Still referring to FIG. 17 and FIG. 18, in one embodiment, the connection electrode 110 electrically connects the isolation structure 700 and the signal connection structure 210, and the connection electrode 110 and the isolation structure 700 are disposed in a same layer and made of a same material. In one embodiment, the connection electrode 110 and the isolation structure 700 are formed integrally. With such a configuration, there is no need to provide an additional film layer structure in the display panel for manufacturing the connection electrode 110, and the connection electrode 110 and the isolation structure 700 may be prepared simultaneously in the same layer using the same preparation process, to simplify the display panel preparation process. Therefore, the connection electrode 110 and the isolation structure 700 are made of the same material and have the same thickness, and the connection electrode 110 and the isolation structure 700 each have a relatively small sheet resistance.

Still referring to FIG. 17 and FIG. 18, in one embodiment, the isolation structure 700 includes a first isolation portion 711 and a second isolation portion 712 that are sequentially stacked in the direction away from the substrate 600, and an orthographic projection of the first isolation portion 711 on the substrate 600 is within that of the second isolation portion 712 on the substrate 600. That is, a size of the first isolation portion 711 is less than that of the second isolation portion 712. With such a configuration, a section shape of the isolation structure 700 forms an undercut structure, and when the light-emitting layer of the light-emitting device 500 in the display panel is deposited, the light-emitting layers of the adjacent light-emitting devices 500 can be cut off at the position of the isolation structure 700.

In one embodiment, the second electrode is electrically connected to the first isolation portion 711. In one embodiment, a second electrode of the light-emitting device 500 may also be formed using the evaporation process. By controlling different evaporation angles for depositing the second electrode and the light-emitting layer, the second electrode may be connected to the first isolation portion 711. In one embodiment, the second electrode laps a side wall of the first isolation portion 711, and all second electrodes of the light-emitting devices 500 in the display panel can be interconnected through the isolation structure 700.

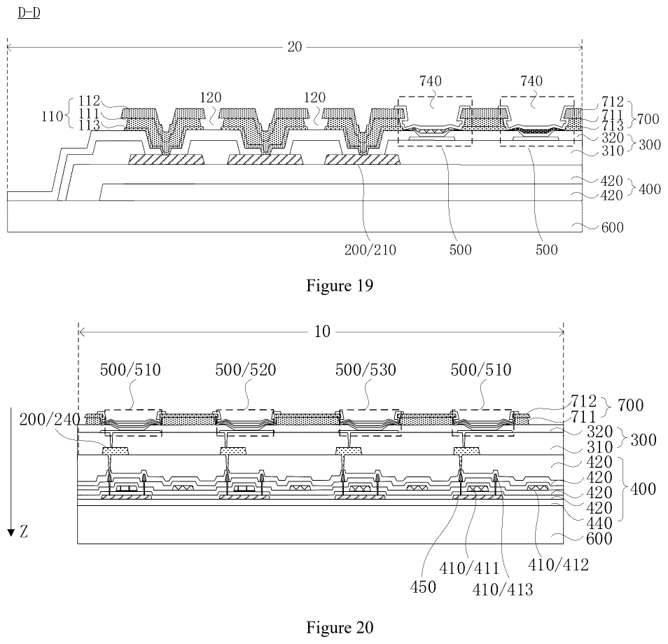

FIG. 19 is a schematic sectional view of yet another display panel according to an embodiment of the present disclosure. Referring to FIG. 19, in another embodiment, the isolation structure 700 further includes a third isolation portion 713 located on a side of the first isolation portion 711 close to the substrate 600. The orthographic projection of the first isolation portion 711 on the substrate 600 is within that of the third isolation portion 713 on the substrate 600, and the second electrode (in one embodiment, the second electrodes 513, 523) is electrically connected to the third isolation portion 713. That is, the size of the first isolation portion 711 is less than that of the third isolation portion 713. With such a configuration, a section shape of the isolation structure 700 forms an undercut structure, and when the light-emitting layer of the light-emitting device 500 in the display panel is deposited, the light-emitting layers of the adjacent light-emitting devices 500 can be cut off at the position of the isolation structure 700. The second electrode of the light-emitting device 500 may also be formed using the evaporation process. By controlling different evaporation angles for depositing the second electrode and the light-emitting layer, the second electrode laps a side wall of the third isolation portion 713, and all second electrodes of the light-emitting devices 500 in the display panel can be interconnected through the isolation structure 700.

In one embodiment, a material of the third isolation portion 713 includes molybdenum metal; and/or a material of the first isolation portion 711 includes aluminum metal; and/or a material of the second isolation portion 712 includes titanium metal. Such a configuration ensures stability of the film layer and reducing the sheet resistance of the connection electrode layer 100, to improve display uniformity.

Still referring to FIG. 19, in an embodiment, the connection electrode 110 includes a first connection electrode portion 111, a second connection electrode portion 112 located on a side of the first connection electrode portion 111 facing away from the substrate 600, and a third connection electrode portion 113 located on a side of the first connection electrode portion 111 facing the substrate 600. The second connection electrode portion 112 protrudes from a side surface of the first connection electrode portion 111, and the third connection electrode portion 113 protrudes from the side surface of the first connection electrode portion 111. Such a configuration facilitates disposition of the first connection electrode portion 111 and the first isolation portion 711 of the isolation structure 700 in the same layer using the same process, and improves a lap effect of the second electrode and the third isolation portion 713 of the isolation structure 700, or improves a lap effect of the second electrode and the third connection electrode portion 113, to enhance stability of signal transmission.

Still referring to FIG. 19, in one embodiment, an orthographic projection of the third connection electrode portion 113 on the substrate 600 is within that of the second connection electrode portion 112 on the substrate 600.

Still referring to FIG. 19, in one embodiment, the first connection electrode portion 111 and the first isolation portion 711 are disposed in a same layer and made of a same material; the second connection electrode portion 112 and the second isolation portion 712 are disposed in a same layer and made of a same material; and the third connection electrode portion 113 and the third isolation portion 713 are disposed in a same layer and made of a same material. Such a configuration allows film layers of the connection electrode 110 and film layers of the isolation structure 700 to be completed in the same preparation process, to eliminate the need for an additional process flow for the connection electrode 110, and to simplify the process flow.

FIG. 20 is a schematic sectional view of yet another display panel according to an embodiment of the present disclosure. Referring to FIG. 20, in one embodiment, the first light-emitting device 510 and the second light-emitting device 520 emit light of different colors. The signal connection structure 210 simultaneously transmits a signal to the first light-emitting device 510 and the second light-emitting device 520. In one embodiment, there is one connection electrode 110. A second electrode 511 of the first light-emitting device 510 is connected to the connection electrode 110, and a second electrode 521 of the second light-emitting device 520 is electrically connected to the connection electrode 110. The connection electrode 110 is connected to both the first light-emitting device 510 and the second light-emitting device 520 to transmit a common potential to the first light-emitting device 510 and the second light-emitting device 520. The connection electrode 110 located in the bezel area 20 transmits the common potential through the signal connection structure 210.

In another embodiment, the signal connection structure 210 includes a first signal connection structure and a second signal connection structure. The first signal connection structure transmits a signal to the first light-emitting device 510, and the second signal connection structure transmits a signal to the second light-emitting device 520. Such a configuration facilitates supply of different common potentials to the light-emitting devices 500 of different colors, to reduce power consumption of the display panel.

Further, the light-emitting device 500 further includes a third light-emitting device. The third light-emitting device emits light of a different color from the first light-emitting device 510 and the second light-emitting device 520. In one embodiment, the first light-emitting device 510 is a green light-emitting device, the second light-emitting device 520 is a red light-emitting device, and the third light-emitting device is a blue light-emitting device. The signal connection structure 210 further includes a third signal connection structure, and the third signal connection structure transmits a signal to the third light-emitting device.

Still referring to FIG. 20, in one embodiment, the display panel further includes at least two second wiring layers 410. In a thickness direction Z of the display panel, a distance between the first wiring layer 200 and the connection electrode layer 100 is less than that between the second wiring layers 410 and the connection electrode layer 100. Such a configuration allows the first wiring layer 200 to be a film layer closer to the connection electrode layer 100, to facilitate a wiring design of the display panel and to reduce difficulty in preparation.

Still referring to FIG. 20, in an embodiment, the at least two second wiring layers 410 are a first metal layer 411, a second metal layer 412, and a third metal layer 413, respectively. The first wiring layer 200 is a fourth metal layer. In one embodiment, the first metal layer 411 is configured to lay out a gate, a scan line, and the like; the second metal layer 412 is configured to lay out capacitor plates and the like; the third metal layer 413 is configured to lay out a source, a drain, a data line, and the like; and the fourth metal layer (i.e., the first wiring layer 200) is configured to lay out a first intermediate trace 240 connected to the first electrode (e.g., the anode), the signal connection structure 210, and the like. The first electrode is located in the first electrode layer, and the first electrode layer is located between the first wiring layer 200 and the connection electrode layer 100.

Still referring to FIG. 20, in one embodiment, the additional film layer 400 of the array layer further includes an intermediate insulating layer 420 between the metal layers, a buffer layer 440, a substrate 430, etc. The intermediate insulating layer 420 includes a gate insulating layer between an active layer 450 and the first metal layer 411, a capacitor insulating layer between the first metal layer 411 and the second metal layer 412, a first intermediate insulating layer between the second metal layer 412 and the third metal layer 413, a second intermediate insulating layer between the third metal layer 413 and the fourth metal layer, a second planarization layer, etc.

In another embodiment, the at least two second wiring layers are a first metal layer, a second metal layer, a third metal layer, and a fourth metal layer, respectively. The first wiring layer is a fifth metal layer. In one embodiment, the first metal layer is configured to lay out a gate, a scan line, and the like; the second metal layer is configured to lay out capacitor plates, and the like; the third metal layer is configured to lay out a source, a drain, a data line, and the like; the fourth metal layer is configured to lay out a first intermediate trace connected to the anode, and the like; and the fifth metal layer (i.e., the first wiring layer) is configured to lay out a third intermediate trace connected to the anode, a crossover line for data lines, the signal connection structure, and the like.

An embodiment of the present disclosure further provides a display panel. Still referring to FIG. 1 to FIG. 20, the display panel has an active area 10 and a bezel area 20 at least partially surrounding the active area 10. The display panel includes:
a substrate 600;
a first electrode layer 501, a light-emitting layer 502, and a second electrode layer 503 that are sequentially stacked in a direction away from the substrate 600;
at least two insulating layers 300 that are located in the bezel area 20 and sequentially stacked in a direction away from the substrate 600, where the at least two insulating layers 300 have nested through holes; and
a connection electrode layer 100 provided with a connection electrode 110 located in the bezel area 20 and a first wiring layer 200 provided with a signal connection structure 210, where the signal connection structure 210 transmits a signal to the connection electrode 110 through the nested holes, and the connection electrode 110 transmits a signal to the second electrode layer 503.

In this embodiment of the present disclosure, the second electrode is configured to be connected to the connection electrode 110, the connection electrode 110 is configured to be connected to the first wiring layer 200 through the nested holes, and the first wiring layer 200 is connected to a desired signal, enabling signal transmission on the connection electrode 110. This embodiment of the present disclosure provides a wiring method for transmitting a signal to the second electrode, which is completely different from the related art, and the flexibility in wiring of the display panel is improved.

Further, in some related technologies, the second electrode layer directly extends from the active area 10 to the bezel area 20 and is connected to a signal transmission line. The second electrode layer is a film layer close to a top layer of the display panel. The second electrode layer in the active area 10 has a complete encapsulation layer for moisture isolation, while the second electrode layer in the bezel area 20 usually has a weak encapsulation (in one embodiment, there is a reduced number of encapsulation layers or no encapsulation layer). Therefore, a wiring structure in the related art is susceptible to moisture ingress, resulting in corrosion. Compared with the second electrode layer, the connection electrode layer 100 is resistant to moisture ingress and is less prone to corrosion.

In one embodiment, the at least two insulating layers 300 include:
a first planarization layer 310 located on a side of the first electrode layer 501 close to the substrate 600 and provided with a first via hole 311 located in the bezel area 20; and
a pixel define layer 320 located on a side of the first electrode layer 501 away from the substrate 600 and provided with a second via hole 321 located in the bezel area 20, where the first via hole 311 and the second via hole 321 form the nested holes.

In one embodiment, an orthographic projection of the first via hole 311 on the substrate 600 overlaps that of the second via hole 321 on the substrate 600, and the connection electrode 110 is connected to the signal connection structure 210 through an overlapping area of the first via hole 311 and the second via hole 321.

In one embodiment, a size of the first via hole 311 is greater than that of the second via hole 321, and the orthographic projection of the first via hole 311 on the substrate 600 covers that of the second via hole 321 on the substrate 600.

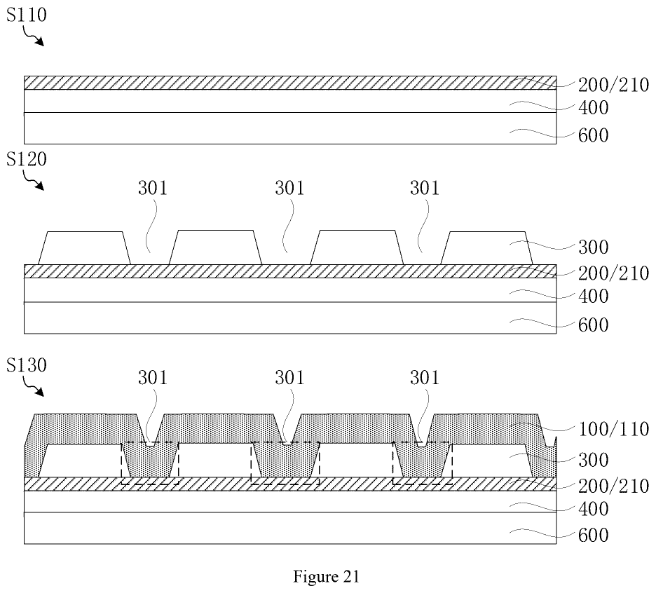

An embodiment of the present disclosure further provides a method for manufacturing a display panel. The manufacturing method may be used to manufacture a display panel according to any embodiment of the present disclosure. FIG. 21 is a schematic structural diagram depicting steps of a method for manufacturing a display panel according to an embodiment of the present disclosure. Referring to FIG. 21, the method for manufacturing a display panel includes the following steps:

S110: Form a first wiring layer 200 on a substrate 600, and perform patterning on the first wiring layer 200 to form a signal connection structure 210 that transmits a signal to a connection electrode 110.

S120: Form an insulating layer 300 on the first wiring layer 200, and form a via hole 301 on the insulating layer 300, where the via hole 301 exposes the signal connection structure 210.

S130: Form a connection electrode layer 100 on the insulating layer 300, and perform patterning on the connection electrode layer 100 to form the connection electrode 110, where the connection electrode 110 is connected to the signal connection structure 210 through the via hole 301.

In this embodiment of the present disclosure, the connection electrode 110 is configured to be connected to the first wiring layer 200 through the via hole 301 on the insulating layer 300, enabling signal transmission on the connection electrode 110. This facilitates signal transmission on the connection electrode 110 and improves the flexibility in wiring of the display panel.

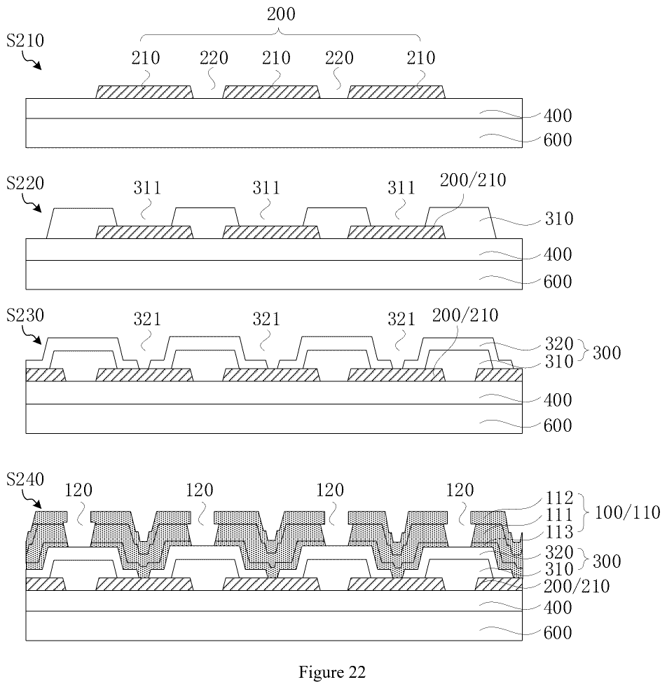

FIG. 22 is a schematic structural diagram depicting steps of another method for manufacturing a display panel according to an embodiment of the present disclosure. Referring to FIG. 22, in one embodiment, the method for manufacturing a display panel includes the following steps:

S210: Form a first wiring layer 200 on a substrate 600, and perform patterning on the first wiring layer 200 to form a signal connection structure 210 that transmits a signal to a connection electrode 110 and a third via hole 220.

In one embodiment, a material of the first wiring layer 200 is a combination of one or more of gold, silver, copper (Cu), lithium (Li), sodium (Na), potassium (K), magnesium (Mg), aluminum (Al), or zinc (Zn). The signal connection structure 210 and the third via hole 220 may be formed by using a photolithography process. In one embodiment, an additional film layer 400 of an array layer is further disposed between the first wiring layer 200 and the substrate 600. An entire metal layer is first formed on the additional film layer 400 of the array layer, and then a photoresist is formed on the metal layer. A pattern of the signal connection structure 210 and the third via hole 220 are formed by a dry etching process, and then the photoresist is removed. Provision of the third via hole 220 facilitates discharge of moisture generated from a lower film layer, to avoid the problem of film layer separation and peeling off caused by the inability to discharge the moisture.

S220: Form a first planarization layer 310 on the first wiring layer 200, and form a first via hole 311 on the first planarization layer 310, where the first via hole 311 exposes the signal connection structure 210.

A material of the first planarization layer 310 is an organic adhesive, which may be a photoresist. In one embodiment, the organic adhesive is applied over the entire first wiring layer 200, and then a patterning process is performed to form the first via hole 311.

S230: Form on the first planarization layer 310 a pixel define layer 320 covering the first planarization layer 310, and form a second via hole 321 on the pixel define layer 320, where the second via hole 321 exposes the signal connection structure 210.

S240: Sequentially, form a third connection electrode portion 113, a first connection electrode portion 111, and a second connection electrode portion 112 on the pixel define layer 320, and perform a photolithography process to form the connection electrode 110 and a fourth via hole 120, where the connection electrode 110 is connected to the signal connection structure 210 through the second via hole 321.

In one embodiment, a material of the third connection electrode portion 113 includes molybdenum, a material of the second connection electrode portion 112 includes aluminum, and a material of the second connection electrode portion 111 includes titanium. The third connection electrode portion 113, the first connection electrode portion 111, and the second connection electrode portion 112 are formed using a physical vapor deposition process, and then the photoresist is applied thereon. The second connection electrode portion 112 and part of the first connection electrode portion 111 are etched using the dry etching process, and then the remaining first connection electrode portion 111 and the third connection electrode portion 113 are etched using a wet etching process, to form the connection electrode 110 and the fourth via hole 120.

It should be noted that for the preparation of the array layer in the display panel, reference may made to a related technology, which is not described in the present disclosure.

An embodiment of the present disclosure further provides a display device. The display device may be a mobile phone, a tablet computer, a wearable device, a computer, a television, etc. The display device includes a display panel according to any of the embodiments of the present disclosure. Principles and generated effects thereof are similar, and details are not described again.

The steps may be reordered, added, or deleted using the various forms of processes illustrated above. In one embodiment, the steps recorded in the present disclosure may be performed in parallel, sequentially, or in a different order, provided that the desired results of the embodiments of the present disclosure can be achieved, which are not limited here.

The detailed description of the above embodiments does not constitute a limitation on the protection of the present disclosure. It is understood that various modifications, combinations, sub-combinations, and substitutions can be made based on design requirements and other factors. Any modifications, equivalent substitutions, or improvements made within the principle of the present disclosure should be included within the protection of the present disclosure.

What is claimed is:

1. A display panel having an active area and a bezel area at least partially surrounding the active area, the display panel comprising:
a substrate;
a first electrode layer, a light-emitting layer, and a second electrode layer sequentially stacked in a direction away from the substrate;
a connection electrode layer located on one side of the substrate and provided with a connection electrode located in the bezel area, wherein the connection electrode is configured to transmit a signal to the second electrode layer; and
a first wiring layer provided with a signal connection structure, wherein the signal connection structure is configured to transmit the signal to the connection electrode.

2. The display panel according to claim 1, further comprising:
an isolation structure disposed on one side of the substrate and provided with a first isolation opening.

3. The display panel according to claim 2, wherein the connection electrode electrically connects the isolation structure and the signal connection structure, and the connection electrode and the isolation structure are disposed in a same layer and made of a same material; and
the connection electrode and the isolation structure are formed integrally.

4. The display panel according to claim 2, further comprising a pixel define layer located on a side of the first electrode layer away from the substrate, wherein the pixel define layer comprises a pixel opening exposing the first electrode, and the pixel opening is in communication with the isolation opening.

5. The display panel according to claim 4, wherein the isolation structure further comprises a second isolation opening located in the bezel area, and the second isolation opening is a dummy isolation opening; and
a size, a shape, an arrangement manner, and a distribution density of the second isolation opening are the same as those of the first isolation opening.

6. The display panel according to claim 4, further comprising a first planarization layer located on a side of the first electrode layer close to the substrate, wherein
the first planarization layer is provided with a first via hole located in the bezel area, and the pixel define layer is provided with a second via hole located in the bezel area;
an orthographic projection of the first via hole on the substrate overlaps an orthographic projection of the second via hole on the substrate, and the connection electrode is connected to the signal connection structure through an overlapping area of the first via hole and the second via hole; and
a size of the first via hole is greater than that of the second via hole, and the orthographic projection of the second via hole on the substrate is within the orthographic projection of the first via hole on the substrate.

7. The display panel according to claim 1, wherein the first wiring layer further comprises a third via hole, and the third via hole is located in the bezel area.

8. The display panel according to claim 7, wherein the third via hole comprises a third via hole A and a third via hole B, an orthographic projection of the third via hole A on the substrate being within an orthographic projection of the connection electrode on the substrate, and an orthographic projection of the third via hole B on the substrate being outside the orthographic projection of the connection electrode on the substrate; and
the display panel further comprises a dam structure located on a side of an area where the signal connection structure is located, the side being away from the active area; the first wiring layer extends from the area where the signal connection structure is located to an area where the dam structure is located; and the orthographic projection of the third via hole B on the substrate overlaps an orthographic projection of the dam structure on the substrate.

9. The display panel according to claim 2, wherein the isolation structure comprises a first isolation portion and a second isolation portion sequentially stacked in the direction away from the substrate, and an orthographic projection of the first isolation portion on the substrate is within an orthographic projection of the second isolation portion on the substrate.

10. The display panel according to claim 9, wherein the second electrode layer comprises a second electrode, and the second electrode is electrically connected to the first isolation portion.

11. The display panel according to claim 9, wherein the second electrode layer comprises a second electrode, and the isolation structure further comprises a third isolation portion located on a side of the first isolation portion close to the substrate, the orthographic projection of the first isolation portion on the substrate being within an orthographic projection of the third isolation portion on the substrate, and the second electrode being electrically connected to the third isolation portion.

12. The display panel according to claim 11, wherein the connection electrode comprises a first connection electrode portion, a second connection electrode portion located on a side of the first connection electrode portion facing away from the substrate, and a third connection electrode portion located on a side of the first connection electrode portion facing the substrate, the second connection electrode portion protruding from a side surface of the first connection electrode portion, and the third connection electrode portion protruding from the side surface of the first connection electrode portion; and
an orthographic projection of the third connection electrode portion on the substrate is within an orthographic projection of the second connection electrode portion on the substrate.

13. The display panel according to claim 12, wherein the first connection electrode portion and the first isolation portion are disposed in a same layer and made of a same material; the second connection electrode portion and the second isolation portion are disposed in a same layer and made of a same material; and the third connection electrode portion and the third isolation portion are disposed in a same layer and made of a same material.

14. The display panel according to claim 1, wherein the connection electrode is of a block shape, and the signal connection structure is of a block shape;
there is at least one connection electrode, and there is at least one signal connection structure; and
electrical signals transmitted on respective connection electrodes are the same; or electrical signals transmitted on respective connection electrodes are different.

15. The display panel according to claim 1, further comprising at least two second wiring layers located between the substrate and the first wiring layer, wherein the at least two second wiring layers comprise a first metal layer, a second metal layer, and a third metal layer; and
at least in the active area, the first metal layer is provided with a gate of a transistor, the second metal layer is provided with capacitor plates, and the third metal layer is provided with a source and a drain of the transistor.

16. The display panel according to claim 1, wherein the first electrode layer comprises a first electrode, the light-emitting layer comprises a light-emitting portion, and the second electrode layer comprises a second electrode, the first electrode, the light-emitting portion, and the second electrode forming a light-emitting device; and
the light-emitting device comprises a first light-emitting device and a second light-emitting device that emit light of different colors, and the signal connection structure comprises a first signal connection structure and a second signal connection structure, the first signal connection structure being electrically connected to the first light-emitting device, and the second signal connection structure being electrically connected to the second light-emitting device.

17. The display panel according to claim 1, wherein the first electrode layer comprises a first electrode, the light-emitting layer comprises a light-emitting portion, and the second electrode layer comprises a second electrode, the first electrode, the light-emitting portion, and the second electrode forming a light-emitting device; and
the light-emitting device comprises a first light-emitting device and a second light-emitting device that emit light of different colors, and the signal connection structure is configured to transmit a same signal to the first light-emitting device and the second light-emitting device.

18. A display device, comprising: a display panel according to claim 1.

19. A display panel having an active area and a bezel area at least partially surrounding the active area, the display panel comprising:
a substrate;
a first electrode layer, a light-emitting layer, and a second electrode layer sequentially stacked in a direction away from the substrate;
at least two insulating layers located in the bezel area and sequentially stacked in a direction away from the substrate, wherein the at least two insulating layers have nested through holes; and
a connection electrode layer provided with a connection electrode located in the bezel area and a first wiring layer provided with a signal connection structure, wherein the signal connection structure is configured to transmit a signal to the connection electrode through the nested holes, and the connection electrode is configured to transmit a signal to the second electrode layer.

20. The display panel according to claim 19, wherein the at least two insulating layers comprise:
a first planarization layer located on a side of the first electrode layer close to the substrate and provided with a first via hole located in the bezel area; and
a pixel define layer located on a side of the first electrode layer away from the substrate and provided with a second via hole located in the bezel area, wherein the first via hole and the second via hole form the nested holes;
an orthographic projection of the first via hole on the substrate overlaps an orthographic projection of the second via hole on the substrate, and the connection electrode is connected to the signal connection structure through an overlapping area of the first via hole and the second via hole; and
a size of the first via hole is greater than that of the second via hole, and the orthographic projection of the first via hole on the substrate covers the orthographic projection of the second via hole on the substrate.
